(19) United States
(12) Patent Application Publication
(10) Pub. No.: US 2026/0205043 A1
(43) Pub. Date: Jul. 16, 2026

(54) SEMICONDUCTOR DEVICE, CURRENT DETECTION SYSTEM, MOTOR DRIVE SYSTEM, AND VEHICLE

(71) Applicant: ROHM Co., LTD., Kyoto (JP)

(72) Inventors: Ryosuke Dogaki, Kyoto (JP); Takashi Fujimura, Kyoto (JP)

(21) Appl. No.: 19/445,364

(22) Filed: Jan. 9, 2026

(30) Foreign Application Priority Data
Jan. 15, 2025 (JP) 2025-005649

(51) Int. Cl. H02P 23/14; G01R 15/14; G01R 19/00

(52) U.S. Cl. CPC H02P 23/14; G01R 15/146; G01R 19/0092

(57) ABSTRACT

Disclosed herein is a semiconductor device including a plurality of first external terminals configured such that a voltage signal as a detection target is applicable thereto, a first amplifier or a first comparator, a plurality of first internal wires each having a first end connected to a respective one of the plurality of first external terminals, a second internal wire having a first end connected to a first input terminal of the first amplifier or the first comparator, and a first switch configured to select one second end to be connected to a second end of the second internal wire from among the second ends of the plurality of first internal wires.

### PRIORITY

The present disclosure contains subject matters related to that disclosed in Japanese Priority Patent Application JP 2025-005649 filed in the Japan Patent Office on January 15, 2025, the entire content of which is hereby incorporated by reference.

### BACKGROUND

The present disclosure relates to a semiconductor device.

A motor drive unit that drives an electric motor has hitherto been known. For example, a motor drive unit that is disclosed in Japanese Patent Laid-open No. 2017-189066 includes a plurality of channels of drivers that each have a pair of half bridges. To each of the half bridges, a shunt resistor is externally connected.

### BRIEF DESCRIPTION OF THE DRAWINGS

FIG. 1 is a diagram illustrating a configuration example of a motor drive system;

FIG. 2 is a diagram illustrating an example in which the motor drive system is configured using a semiconductor device;

FIG. 3 is a diagram illustrating an internal configuration example of a semiconductor device according to an embodiment of the present disclosure;

FIG. 4 is a diagram illustrating a first use example in which a motor drive system is configured using the semiconductor device;

FIG. 5 is a diagram schematically illustrating an internal configuration of the semiconductor device;

FIG. 6 is a diagram illustrating a second use example in which the motor drive system is configured using the semiconductor device;

FIG. 7 is a diagram illustrating a third use example in which the motor drive system is configured using the semiconductor device;

FIG. 8 is a diagram schematically illustrating an internal configuration of a semiconductor device according to a modification;

FIG. 9 is a diagram illustrating an internal configuration of a semiconductor device according to a modification; and

FIG. 10 is a diagram of an external appearance illustrating one configuration example of a vehicle.

### DETAILED DESCRIPTION

Hereinafter, an illustrative embodiment of the present disclosure will be explained with reference to the drawings.

### Configuration of Motor Drive System

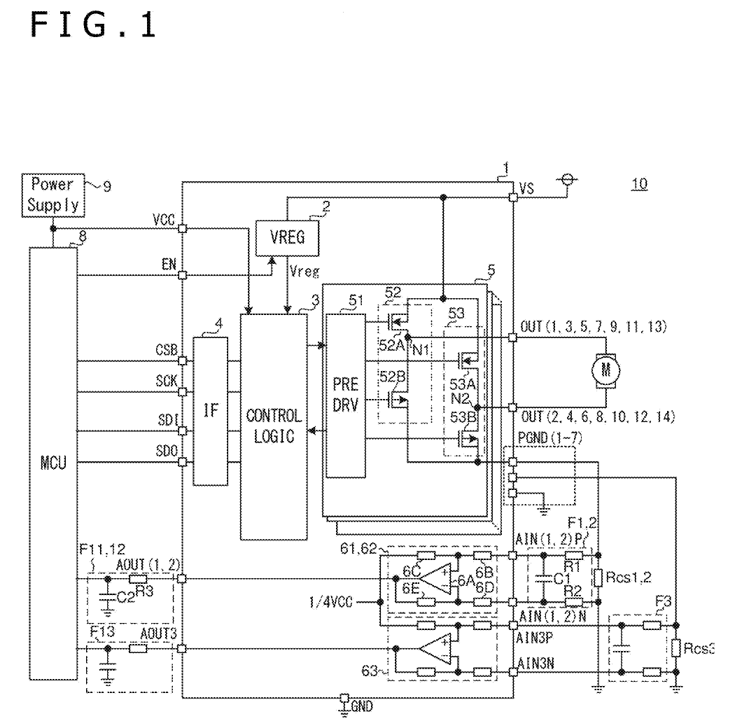

FIG. 1 is a diagram illustrating a configuration example of a motor drive system. A motor drive system 10 illustrated in FIG. 1 includes a semiconductor device 1, a micro controller unit 8, and a power supply circuit 9. The semiconductor device 1 is configured as a motor driver that drives an electric motor M that is a brushed direct current (DC) motor.

The semiconductor device 1 includes, as external terminals for establishing electrical connection with the outside, a VCC terminal, an EN terminal, a CSB terminal, an SCK terminal, an SDI terminal, an SDO terminal, an AOUT 1 terminal, an AOUT 2 terminal, an AOUT 3 terminal, an AIN1P terminal, an AIN1N terminal, an AIN2P terminal, an AIN2N terminal, an AIN3P terminal, an AIN3N terminal, PGND1 through PGND7 terminals, OUT1 through OUT14 terminals, a VS terminal, and a GND terminal.

The semiconductor device 1 has, as an internal configuration, an internal power supply circuit 2, a control unit (control logic) 3, an interface 4, a driver 5, and current detection amplifiers 61 through 63 that are integrated.

The internal power supply circuit 2 generates an internal power supply voltage Vreg according to a power supply voltage VS applied to the VS terminal. The internal power supply voltage Vreg is supplied to the control unit 3, for example.

A power supply voltage VCC output from the power supply circuit 9 is supplied to, for example, the control unit 3 via the VCC terminal, as well as to the micro controller unit 8. An enable signal EN output from the micro controller unit 8 is input to the internal power supply circuit 2 via the EN terminal. Start-up and shut-down of the internal power supply circuit 2 is performed according to the enable signal EN.

The interface 4 performs serial peripheral interface (SPI) communication with the micro controller unit 8 via the CSB terminal, the SCK terminal, the SDI terminal, and the SDO terminal. The CSB terminal is a terminal for chip selection input. The SCK terminal is a terminal for clock input. The SDI terminal is a terminal for data input. The SDO terminal is a terminal for data output.

The control unit 3 controls the driver 5 and other components. The driver 5 drives the electric motor M by supplying a current to the electric motor M. The driver 5 is provided for a plurality of channels, for example, seven channels. As a configuration for one channel, the driver 5 includes a predriver 51, a half bridge 52, and a half bridge 53.

The half bridge 52 includes an upper side transistor 52A and a lower side transistor 52B. The upper side transistor 52A is configured by a P-channel metal-oxide-semiconductor field-effect transistor (MOSFET), while the lower side transistor 52B is configured by an N-channel MOSFET. The half bridge 53 includes an upper side transistor 53A and a lower side transistor 53B. The upper side transistor 53A is configured by a P-channel MOSFET, while the lower side transistor 53B is configured by an N-channel MOSFET. Each source of the upper side transistors 52A and 53A is connected to the VS terminal. A drain of the upper side transistor 52A is connected to a drain of the lower side transistor 52B by a node N1. A drain of the upper side transistor 53A is connected to a drain of the lower side transistor 53B by a node N2. Each source of the lower side transistors 52B and 53B is connected to a PGNDx terminal (x is any one of 1 through 7). That is, the PGNDx terminal is provided for seven channels.

The node N1 is connected to the OUTx terminal (x is any one of 1, 3, 5, 7, 9, 11, and 13). The node N2 is connected to the OUTy terminal (y is any one of 2, 4, 6, 8, 10, 12, and 14). Note that (x, y) is a pair of (1, 2), (3, 4), (5, 6), (7, 8), (9, 10), (11, 12), and (13, 14) and the OUTx terminal and the OUTy terminal are provided for seven channels.

The electric motor M is connected to and between the corresponding OUTx terminal and OUTy terminal. That is, the semiconductor device 1 is able to drive the electric motors M for seven channels at maximum.

The PGNDx terminal is able to select any one of current detection using the current detection amplifier 61, current detection using the current detection amplifier 62, current detection using the current detection amplifier 63, and no current detection for each channel.

The current detection amplifier 61 is provided in a manner corresponding to a pair including the AIN1P terminal and the AIN1N terminal, and the current detection amplifier 62 is provided in a manner corresponding to a pair including the AIN2P terminal and the AIN2N terminal. The current detection amplifier 63 is provided in a manner corresponding to a pair including the AIN3P terminal and the AIN3N terminal. That is, in the semiconductor device 1, the current detection amplifier is provided for three channels.

In a case where current detection using the current detection amplifier 61 is selected, a shunt resistor Rcs1 and an input filter F1 are provided between any of the PGNDx terminals and the AIN1P terminal and AIN1N terminal. The input filter F1 includes resistors R1 and R2 and a capacitor C1. The shunt resistor Rcs1 and the input filter F1 that are provided outside the semiconductor device 1 are included in the motor drive system 10. The shunt resistor Rcs1 is connected to and between the PGNDx terminal and a ground end. One end of the shunt resistor Rcs1 is connected to the PGNDx terminal and one end of the resistor R1. The other end of the shunt resistor Rcs1 is connected to the ground end and one end of the resistor R2. The other end of the resistor R1 is connected to the AIN1P terminal and one end of the capacitor C1. The other end of the resistor R2 is connected to the AIN1N terminal and the other end of the capacitor C1.

In a case where current detection using the current detection amplifier 62 is selected, a shunt resistor Rcs2 and an input filter F2 are provided between any of the PGNDx terminals and the AIN2P terminal and AIN2N terminal. The configuration of the input filter F2 is similar to that of the input filter F1.

The current detection amplifier 61 is provided in a manner corresponding to the AIN1P terminal and the AIN1N terminal. The current detection amplifier 61 is a differential amplifier circuit that amplifies the voltage between the AIN1P terminal and the AIN1N terminal. The current detection amplifier 61 includes an operational amplifier 6A and resistors 6B through 6E. One end of the resistor 6B is connected to the AIN1P terminal. The other end of the resistor 6B is connected to a non-inverting input terminal (+) of the operational amplifier 6A and one end of the resistor 6C. The other end of the resistor 6C is connected to an application terminal of a voltage of 1/4 of the power supply voltage VCC. One end of the resistor 6D is connected to the AIN1N terminal. The other end of the resistor 6D is connected to an inverting input terminal (-) of the operational amplifier 6A and one end of the resistor 6E. The other end of the resistor 6E is connected to an output terminal of the operational amplifier 6A.

The current detection amplifier 62 is provided in a manner corresponding to the AIN2P terminal and the AIN2N terminal and is a differential amplifier circuit that amplifies the voltage between the AIN2P terminal and the AIN2N terminal. The configuration of the current detection amplifier 62 is similar to that of the current detection amplifier 61.

The output terminal of the current detection amplifier 61 (operational amplifier 6A) is connected to the AOUT1 terminal. The AOUT1 terminal is connected to an input terminal of an output filter F11 provided outside the semiconductor device 1. The output filter F11 includes a resistor R3 and a capacitor C2 and is included in the motor drive system 10. With such a configuration, the voltage obtained by current/voltage conversion of the current flowing through the shunt resistor Rcs1 is input via the input filter F1 to the current detection amplifier 61 and amplified therein. The amplified voltage is then input to the micro controller unit 8 via the output filter F11.

An output terminal of the current detection amplifier 62 is connected to the AOUT2 terminal. The AOUT2 terminal is connected to an input terminal of an output filter F12 provided outside the semiconductor device 1. The configuration of the output filter F12 is similar to that of the output filter F11. With such a configuration, the voltage obtained by current/voltage conversion of the current flowing through the shunt resistor Rcs2 is input via the input filter F2 to the current detection amplifier 62 and amplified therein. The amplified voltage is then input to the micro controller unit 8 via the output filter F12.

In a case where current detection using the current detection amplifier 63 is selected, a shunt resistor Rcs3 and an input filter F3 are provided between any of the PGNDx terminals and the AIN3P terminal and AIN3N terminal. The configuration of the input filter F3 is similar to those of the input filters F1 and F2.

The current detection amplifier 63 is provided in a manner corresponding to the AIN3P terminal and the AIN3N terminal and is a differential amplifier circuit that amplifies the voltage between the AIN3P terminal and the AIN3N terminal. The configuration of the current detection amplifier 63 is similar to those of the current detection amplifiers 61 and 62.

An output terminal of the current detection amplifier 63 is connected to the AOUT3 terminal. The AOUT3 terminal is connected to an input terminal of an output filter F13 provided outside the semiconductor device 1. The configuration of the output filter F13 is similar to those of the output filters F11 and F12. With such a configuration, the voltage obtained by current/voltage conversion of the current flowing through the shunt resistor Rcs3 is input via the input filter F3 to the current detection amplifier 63 and amplified therein. The amplified voltage is then input to the micro controller unit 8 via the output filter F13.

Note that, in a case where no current detection is to be performed for the PGNDx terminals, the PGNDx terminals are connected to the ground end.

### Problem of Semiconductor Device

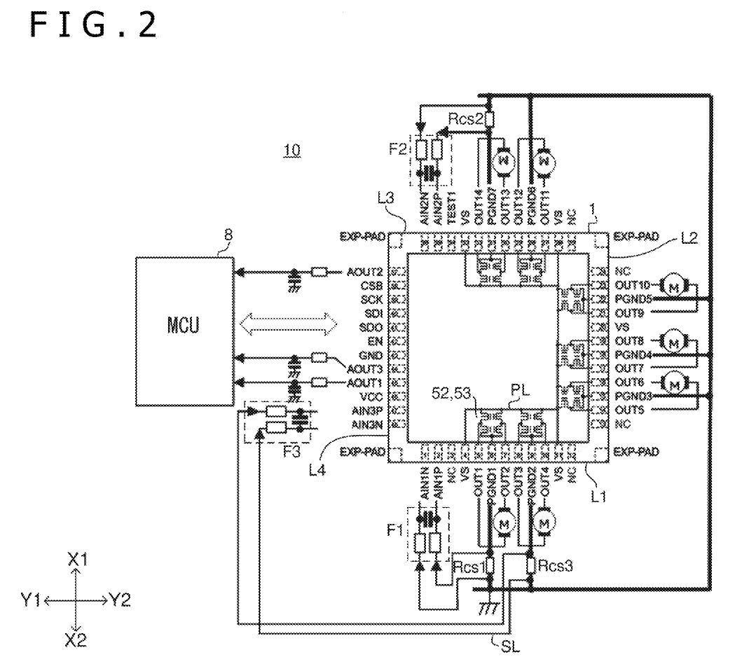

FIG. 2 is a diagram illustrating an example in which the motor drive system 10 is configured using the semiconductor device 1. As illustrated in FIG. 2, inside the semiconductor device 1, a pair of half bridges 52 and 53 are provided for seven channels. The PGNDx terminal is provided for each pair of half bridges 52 and 53. Note that all of the pairs of half bridges 52 and 53 are connected in common to a power supply line PL to which a power supply voltage VS is applied.

FIG. 2 is a plan view of the semiconductor device 1 as viewed from above. FIG. 2 illustrates the layout of the external terminals (pin number 1 through 48). In FIG. 2, one side X1 of a first direction and the other side X2 of the first direction are illustrated as a first direction X (up-down direction on the sheet), while one side Y1 of a second direction and the other side Y2 of the second direction are illustrated as a second direction Y (left-right direction on the sheet). The first direction X and the second direction Y are orthogonal to each other.

The semiconductor device 1 has a rectangular shape in top view and includes a first side L1, a second side L2, a third side L3, and a fourth side L4. The first side L1 and the third side L3 extend in the second direction Y, while the second side L2 and the fourth side L4 extend in the first direction X. The first side L1 and the third side L3 face each other in the first direction X, while the second side L2 and the fourth side L4 face each other in the second direction Y. An end on the other side Y2 of the second direction of the first side L1 is connected to an end on the other side X2 of the first direction of the second side L2. An end on the one side X1 of the first direction of the second side L2 is connected to an end on the other side Y2 of the second direction of the third side L3. An end on the one side Y1 of the second direction of the third side L3 is connected to an end on the one side X1 of the first direction of the fourth side L4. An end on the other side X2 of the first direction of the fourth side L4 is connected to an end on the one side Y1 of the second direction of the first side L1.

Regarding the PGNDx terminals provided for seven channels as described above, the PGND1 and PGND2 terminals are provided on the first side L1, the PGND3, PGND4, and PGND5 terminals are provided on the second side L2, and the PGND6 and PGND7 terminals are provided on the third side L3. The PGND1 through PGND7 terminals are arranged in such a manner that the PGND1 terminal is sandwiched by the OUT1 and OUT2 terminals, the PGND2 terminal is sandwiched by the OUT3 and OUT4 terminals, the PGND3 terminal is sandwiched by the OUT5 and OUT6 terminals, the PGND4 terminal is sandwiched by the OUT7 and OUT8 terminals, the PGND5 terminal is sandwiched by the OUT9 and OUT10 terminals, the PGND6 terminal is sandwiched by the OUT11 and OUT12 terminals, and the PGND7 terminal is sandwiched by the OUT13 and OUT14 terminals.

In the example illustrated in FIG. 2, the shunt resistor Rcs1 is connected to the PGND1 terminal, the shunt resistor Rcs2 is connected to the PGND7 terminal, and the shunt resistor Rcs3 is connected to the PGND2 terminal. From both ends of each of the shunt resistors Rcs1, Rcs2, and Rcs3, a sense line SL for current detection is drawn out and is connected to the input filters F1, F2, and F3.

Performing current detection in a plurality of channels with use of the shunt resistors as described above had the problem of complicated substrate wiring around the semiconductor device 1. This sometimes resulted in a more complicated substrate design due to the necessity of taking into consideration noise and routing the sense line on the substrate, making it difficult to reduce the size of the substrate. Moreover, providing an input filter for a plurality of channels also hindered size reduction of substrates.

### Switch

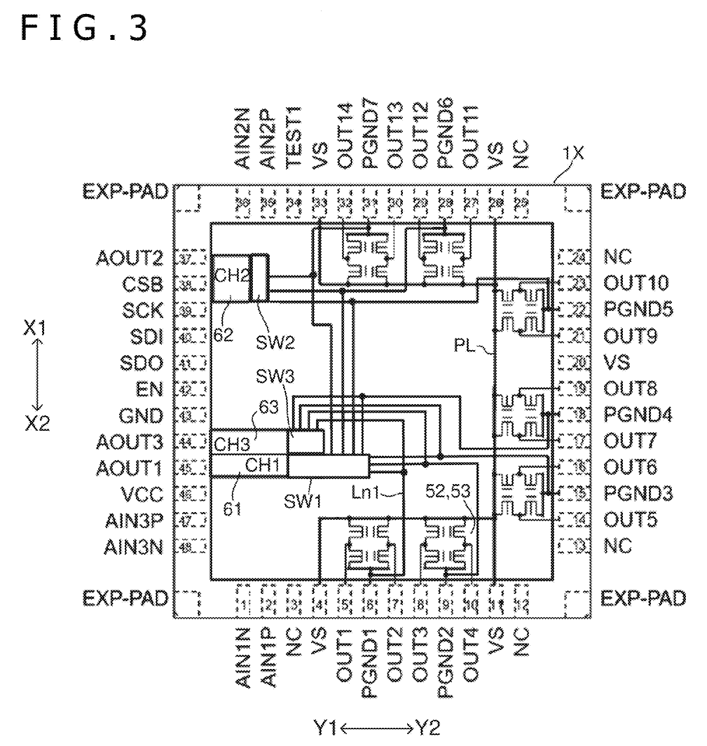

In view of the problem described above, the following embodiment of the present disclosure is implemented. FIG. 3 is a diagram illustrating an internal configuration example of a semiconductor device 1X according to the embodiment of the present disclosure. In the semiconductor device 1X illustrated in FIG. 3, switches SW1 through SW3 are provided in a manner corresponding to the respective current detection amplifiers 61 through 63.

FIG. 3 illustrates the layout of the current detection amplifiers 61 through 63 and the switches SW1 through SW3. The current detection amplifier 61 (detection channel CH1) is arranged in the vicinity of the AOUT1 terminal. The switch SW1 is provided adjacent to the current detection amplifier 61 on the other side Y2 of the second direction. The current detection amplifier 63 (detection channel CH3) is arranged in the vicinity of the AOUT3 terminal. The switch SW3 is provided adjacent to the current detection amplifier 63 on the other side Y2 of the second direction. The current detection amplifier 62 (detection channel CH2) is arranged in the vicinity of the AOUT2 terminal. The switch SW2 is provided adjacent to the current detection amplifier 62 on the other side Y2 of the second direction.

Each of the PGND1 through PGND7 terminals is connected to the switch SW1 by the respective one of seven internal wires Ln1. Each of the PGND1 through PGND4 terminals is connected to the switch SW3 by the respective one of four internal wires Ln1. Each of the PGND5 through PGND7 terminals is connected to the switch SW2 by the respective one of three internal wires Ln1.

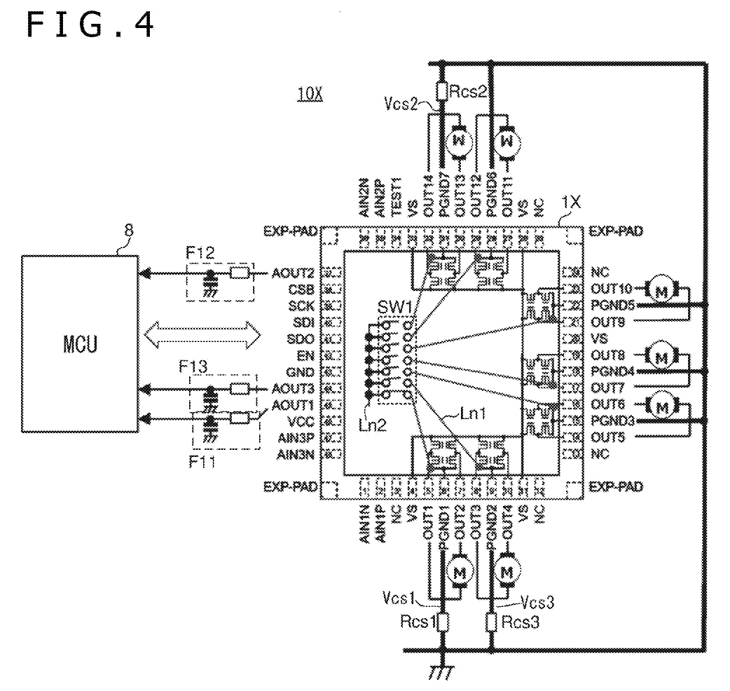

FIG. 4 illustrates a representative example of a specific configuration of the switch SW1 in the semiconductor device 1X. As illustrated in FIG. 4, a first end of each of the seven internal wires Ln1 is connected to the respective one of the PGND1 through PGND7 terminals. A second end of each of the internal wires Ln1 is connected to a first end of the switch SW1. The connection between the switch SW2 or SW3 and the PGNDx terminals is similar to the abovementioned connection.

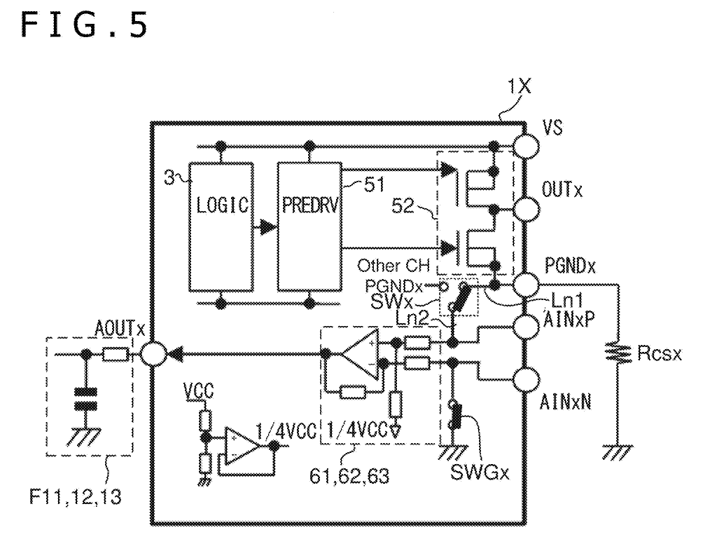

A second end of each of the switches SW1, SW2, and SW3 is connected to a first input terminal of the respective one of the current detection amplifiers 61 through 63 by each of three internal wires Ln2. Here, FIG. 5 is a diagram schematically illustrating the internal configuration of the semiconductor device 1X. As illustrated in FIG. 5, a first end of the internal wire Ln2 is connected to the first input terminal (one end of the resistor 6B) of each of the current detection amplifiers 61 through 63. A second end of the internal wire Ln2 is connected to a second end of a switch SWx.

The switch Swx is configured to select one second end to be connected to the second end of the internal wire Ln2 from among the second ends of the plurality of internal wires Ln1. For example, in the case of the switch SW1, any one of the internal wires Ln1 connected to each of the PGND1 through PGND7 terminals is selected to be connected to the internal wire Ln2.

Note that, as illustrated in FIG. 5, in the semiconductor device 1X, a grounding switch SWGx is provided between a second input terminal (one end of the resistor 6D) of each of the current detection amplifiers 61 through 63 and the ground end. In a case of using an AINxP terminal and an AINxN terminal, the grounding switch SWGx is turned off. In contrast, in a case of using the switch Swx, that is, in a case where the AINxP terminal and the AINxN terminal are not used, the grounding switch SWGx is turned on.

### First Use Example

FIG. 4, which has already been described, is a diagram illustrating a first use example in which a motor drive system 10X is configured using the semiconductor device 1X. Here, as in FIG. 2, which has already been described, the shunt resistor Rcs1 is connected to the PGND1 terminal, the shunt resistor Rcs3 is connected to the PGND2 terminal, and the shunt resistor Rcs2 is connected to the PGND7 terminal. Note that current detection is not performed for the PGND3 through PGND6 terminals, and the PGND3 through PGND6 terminals are connected to the ground end.

As illustrated in FIG. 4, the switch SW1 is selecting the PGND1 terminal. As a result, a current detection signal Vcs1 as a voltage signal generated by current/voltage conversion in the shunt resistor Rcs1 is input via the internal wire Ln1, the switch SW1, and the internal wire Ln2 to the first input terminal of the current detection amplifier 61 and amplified therein.

Further, the switch SW3, which is not illustrated in FIG. 4, is selecting the PGND2 terminal. As a result, a current detection signal Vcs3 generated by current/voltage conversion in the shunt resistor Rcs3 is input via the internal wire Ln1, the switch SW3, and the internal wire Ln2 to the first input terminal of the current detection amplifier 63 and amplified therein.

Further, the switch Sw2, which is not illustrated in FIG. 4, is selecting the PGND7 terminal. As a result, a current detection signal Vcs2 generated by current/voltage conversion in the shunt resistor Rcs2 is input via the internal wire Ln1, the switch SW2, and the internal wire Ln2 to the first input terminal of the current detection amplifier 62 and amplified therein.

As described above, according to the present embodiment, the sense line which had been drawn out from the shunt resistor in the already-described configuration of FIG. 2 is incorporated in the semiconductor device 1X as the internal wires Ln1 and LN2, so that the substrate wiring around the semiconductor device 1X can be simplified. As a result, the substrate can be reduced in size and weight, and can be designed more easily. Moreover, providing the output filters F11 through F13 (FIG. 4) can serve as measures for noise without providing input filters in the substrate.

Further, for example, according to the switch SW1, any one of the PGND1 through PGND7 terminals can be selected, so that not only the case where the shunt resistor is connected to the PGND1 terminal as in FIG. 4 but also the case where the shunt resistor is connected to any of the PGND2 through PGND7 terminals can be handled by switching of the switch SW1.

Further, since the switch SW1 is able to select any one of the PGND1 through PGND7 terminals, the switch SW3 is able to select any of the PGND1 through PGND4 terminals, and the switch SW2 is able to select any one of the PGND5 through PGND7 terminals, the shunt resistor can be connected to the PGNDx terminal within the range selectable by each of the switches. That is, providing a plurality of switches allows handling of various patterns of current detection in a plurality of channels. As described above, according to the present embodiment, flexible handling can be made according to the specification used by a user of the semiconductor device 1X.

Note that, for example, the switch SW1 may be able to select the PGND1 through PGND3 terminals, the switch SW2 may be able to select the PGND4 and PGND5 terminals, and the switch SW3 may be able to select the PGND6 and PGND7 terminals. That is, the selectable channel may not overlap between the plurality of switches.

### Second Use Example

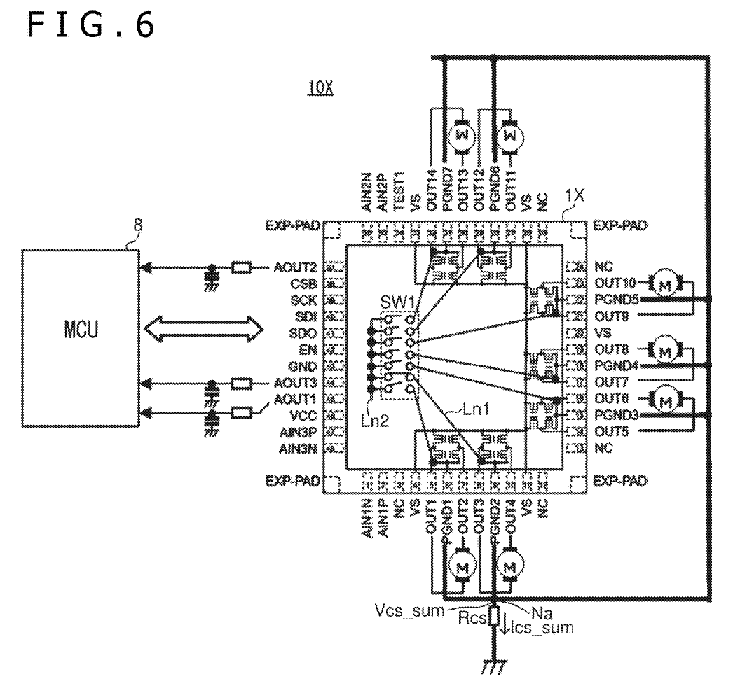

FIG. 6 is a diagram illustrating a second use example in which the motor drive system 10X is configured using the semiconductor device 1X. Here, the PGND1 through PGND 7 terminals (that is, all of the channels) are short-circuited outside the semiconductor device 1X, and a shunt resistor Rcs is connected to a short-circuited node Na. As a result, a total current Ics_sum, which is the total amount of current flowing through each of the PGND1 through PGND7 terminals, is subjected to current/voltage conversion by the shunt resistor Rcs, as Vcs_sum = Ics_sum × Rcs, and a total current detection signal Vcs_sum is generated in the node Na. The switch SW1 is set to select the PGNDx terminal which has the shortest wiring between the shunt resistor Rcs and the PGNDx terminal. In the example illustrated in FIG. 6, the switch SW1 is selecting the PGND2 terminal. Consequently, the total current detection signal Vcs_sum is input via the internal wire Ln1, the switch SW1, and the internal wire Ln2 to the first input terminal of the current detection amplifier 61 and amplified therein.

As described above, according to the present embodiment, even in a case where the total current of all of the channels is to be detected, switches for selecting each PGNDx terminal are provided, so that there are no arrangement constraints for providing a shunt resistor Rcs, realizing excellent flexibility corresponding to user specification.

### Third Use Example

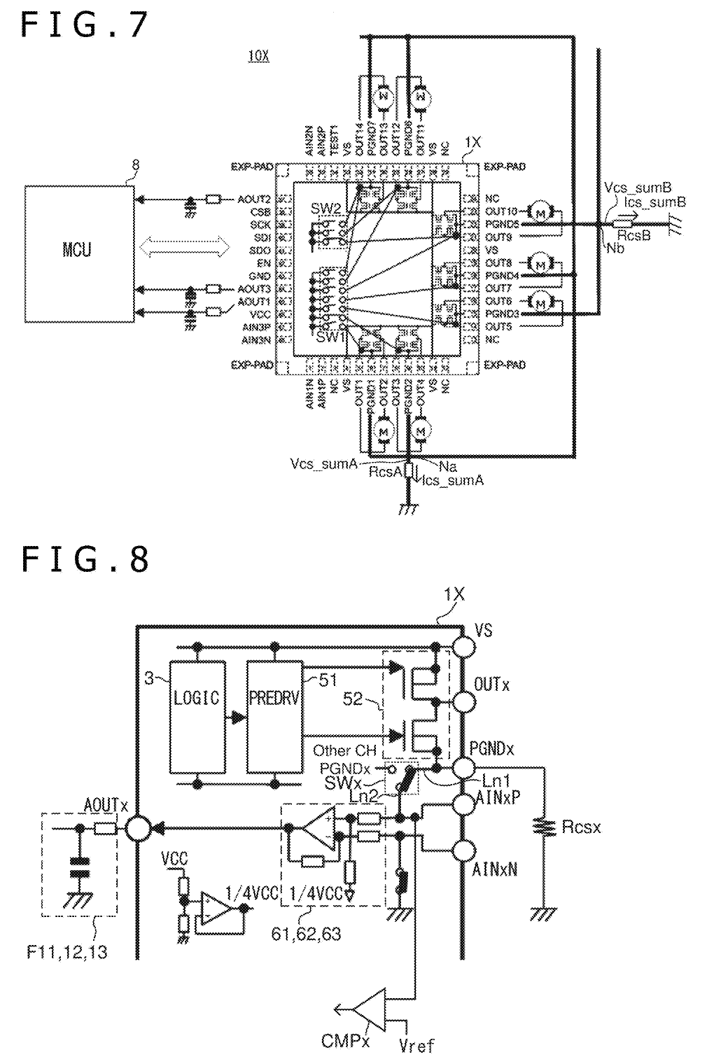

FIG. 7 is a diagram illustrating a third use example in which the motor drive system 10X is configured using the semiconductor device 1X. Here, the PGND1, PGND2, PGND4, PGND6, and PGND7 terminals are short-circuited, and a shunt resistor RcsA is connected to the short-circuited node Na. Further, the PGND3 and PGND5 terminals are short-circuited, and a shunt resistor RcsB is connected to a short-circuited node Nb. As a result, the total current Ics_sumA, which is the total amount of current flowing through each of the PGND1, PGND2, PGND4, PGND6, and PGND7 terminals, is subjected to current/voltage conversion by the shunt resistor RcsA, as Vcs_sumA = Ics_sumA × RcsA, and a total current detection signal Vcs_sumA is generated in the node Na, while a total current Ics_sumB, which is the total amount of current flowing through each of the PGND3 and PGND5 terminals, is subjected to current/voltage conversion by the shunt resistor RcsB, as Vcs_sumB = Ics_sumB × RcsB, and a total current detection signal Vcs_sumB is generated in the node Nb.

In the example illustrated in FIG. 7, the PGND2 terminal, which has the shortest wiring to the shunt resistor RcsA, is selected by the switch SW1 from among the PGND1, PGND2, PGND4, PGND6, and PGND7 terminals connected to the switch SW1. Moreover, the PGND5 terminal connected to the switch SW2 is selected by the switch SW2 from among the PGND3 and PGND5 terminals. As a result, the total current detection signals Vcs_sumA and Vcs_sumB are respectively input via the switches SW1 and SW2 to the current detection amplifiers 61 and 62 and amplified therein.

As described above, the PGNDx terminals can freely be classified into a plurality of groups, and the total current detection signal detected for each group can be selected by each switch and amplified.

### Overcurrent Detection

FIG. 8 is a diagram schematically illustrating an internal configuration of a semiconductor device 1X according to a modification. In the modification, the semiconductor device 1X includes a comparator CMPx. The comparator CMPx is provided to detect overcurrent. The first end of the internal wire Ln2 is connected to a first input terminal of the comparator CMPx. A second input terminal of the comparator CMPx is connected to an application terminal of a reference voltage Vref. As a result, the current detection signal detected by the PGNDx terminal is compared with the reference voltage Vref by the comparator CMPx, and generation of overcurrent is detected when the current detection signal exceeds the reference voltage Vref. This allows flexible overcurrent detection corresponding to user specification.

### Various Modifications

In the present disclosure, various modifications as described below can be implemented. For example, in the semiconductor device 1X according to the embodiment described above, the AINxP terminal and the AINxN terminal can be deleted. This can reduce the size of the semiconductor device 1X. Note that, in this case, it is sufficient if the second input terminal of the current detection amplifier is constantly connected to the ground end without the grounding switch SWGx being provided.

Moreover, the PGNDx terminal is not limited to being provided for each pair of half bridges as in the embodiment described above, and may be provided for each half bridge or for each unit including a plurality of pairs of half bridges.

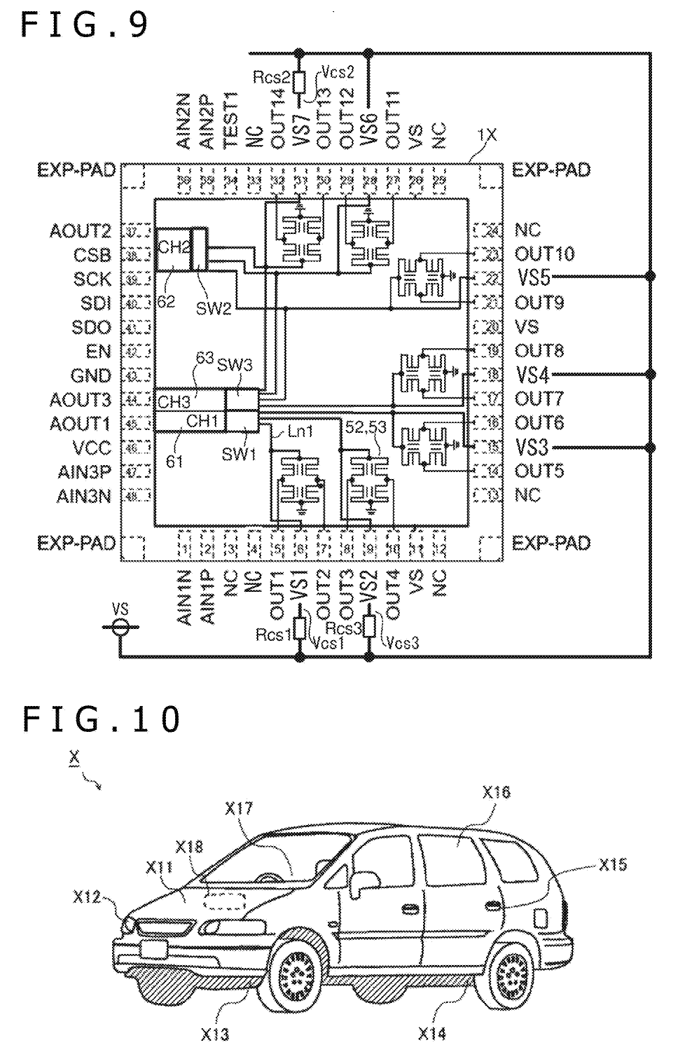

Further, overcurrent detection may be performed with a shunt resistor being provided on the VS terminal side instead of being provided on the PGND terminal side. As a specific example, FIG. 9 is a diagram illustrating an internal configuration of a semiconductor device 1X according to a modification. In the configuration illustrated in FIG. 9, the semiconductor device 1X includes the VS1 terminal sandwiched by the OUT1 and OUT2 terminals, the VS2 terminal sandwiched by the OUT3 and OUT4 terminals, the VS3 terminal sandwiched by the OUT5 and OUT6 terminals, the VS4 terminal sandwiched by the OUT7 and OUT8 terminals, the VS5 terminal sandwiched by the OUT9 and OUT10 terminals, the VS6 terminal sandwiched by the OUT11 and OUT12 terminals, and the VS7 terminal sandwiched by the OUT13 and OUT14 terminals.

The VS1 through VS7 terminals are respectively connected to a source of each of the upper side transistors 52A and 53A of the pair of half bridges 52 and 53. Each of the VS1 and VS7 terminals is connected to the switch SW1 by the respective one of seven internal wires Ln1. Each of the VS1 through VS4 terminals is connected to the switch SW3 by the respective one of four internal wires Ln1. Each of the VS5 through VS7 terminals is connected to the switch SW2 by the respective one of three internal wires Ln1.

While the VS1 through VS7 terminals can be connected to the application terminal of the power supply voltage VS, a shunt resistor can freely be inserted at that time. In the configuration illustrated in FIG. 9, as one example, the shunt resistors Rcs1, Rcs3, and Rcs2 are respectively provided for the VS1, VS2, and VS7 terminals. Selecting the VS1, VS2, and VS7 terminals respectively by the switches SW1, SW3, and SW2 makes it possible to supply via the switches SW1, SW3, and SW2 current detection signals Vcs1, Vcs3, and Vcs2 generated by the shunt resistors Rcs1, Rcs3, and Rcs2 to the current detection amplifiers 61, 63, and 62 and have the current detection signals amplified in the respective current detection amplifiers.

Moreover, the semiconductor device according to the present disclosure may be applied not only to current detection in a motor drive system but also to current detection in an application other than the motor drive system. Further, the semiconductor device according to the present disclosure may be applied not only for current detection but also for voltage detection. That is, the target of amplification by an amplifier or comparison by a comparator is not limited to a signal generated by current/voltage conversion.

### Vehicle

FIG. 10 is a diagram of an external appearance illustrating one configuration example of a vehicle X. The vehicle X according to the present configuration example has various kinds of electronic devices X11 through X18 that operate by receiving supply of electric power from an unillustrated battery. Note that the installation positions of the electronic devices X11 through X18 in FIG. 10 may be illustrated to be different from the actual positions, for convenience of illustration.

The electronic device X11 is an engine control unit that performs control related to an engine (e.g., injection control, electronic throttle control, idling control, oxygen sensor heater control, or auto cruise control).

The electronic device X12 is a lamp control unit that performs light ON/OFF control of a high intensity discharged lamp (HID), a daytime running lamp (DRL), etc.

The electronic device X13 is a transmission control unit that performs control related to transmission.

The electronic device X14 is a body control unit that performs control related to motion of the vehicle X (anti-lock brake system (ABS) control, electric power steering (EPS) control, electronic suspension control, etc.).

The electronic device X15 is a security control unit that controls driving of a door lock or a crime prevention alarm.

The electronic device X16 is an electronic device installed in the vehicle X in a factory shipping stage, as a standard accessory or an option provided by a manufacturer, such as a wiper, an electric door mirror, a power window, a damper (shock absorber), an electric sunroof, or an electric seat.

The electronic device X17 is an electronic device as exemplified by an on-vehicle audio/visual (A/V) device, a car navigation system, or an electronic toll collection system (ETC), which is optionally mounted on the vehicle X as a user option product.

The electronic device X18 is an electronic device equipped with a high voltage resistance motor as exemplified by an on-vehicle blower, an oil pump, a water pump, or a battery cooling fan.

Note that the motor drive system including the semiconductor device 1X described above may be applied to any one of the electronic devices X11 through X18.

### Others

Note that, aside from the embodiment described above, various technical features disclosed in the present description can variously be modified without deviating from the gist of the technical creation. In other words, the embodiment described above is for illustrative purposes alone in every aspect and should not be interpreted as limitations. The technical scope of the present disclosure is not limited to the abovementioned embodiment and should be understood to encompass all modifications thereof within the meanings and scopes equivalent to the claims.

### Supplement

As described above, a semiconductor device (1X) according to an aspect of the present disclosure has a configuration (first configuration) including:

a plurality of first external terminals (PGND1 through PGND7) configured such that a voltage signal as a detection target is applicable thereto;

a first amplifier (61) or a first comparator (CMP1);

a plurality of first internal wires (Ln1) each having a first end connected to a respective one of the plurality of first external terminals;

a second internal wire (Ln2) having a first end connected to a first input terminal of the first amplifier or the first comparator; and

a first switch (SW1) configured to select one second end to be connected to a second end of the second internal wire from among the second ends of the plurality of first internal wires.

According to such a configuration, which of the first external terminals is to detect the voltage signal as the detection target can be decided flexibly according to user specification.

Further, in the first configuration described above, the semiconductor device may have a configuration (second configuration) in which each of the first external terminals is configured to allow a shunt resistor (Rcsx) for current/voltage conversion to be externally connected thereto.

Further, in the second configuration described above, the semiconductor device may have a configuration (third configuration) in which each of the first external terminals is a ground terminal (PGNDx) connectable to a ground end via the shunt resistor.

Further, in the second configuration described above, the semiconductor device may have a configuration (fourth configuration) in which each of the first external terminals is a power supply terminal (VSx) connectable to an application terminal of a power supply voltage (VS) via the shunt resistor.

Further, in the third or fourth configuration described above, the semiconductor device may have a configuration (fifth configuration) in which

a half bridge (52, 53) is configured such that an upper side transistor (52A, 53A) and a lower side transistor (52B, 53B) are connected in series,

the semiconductor device includes a plurality of channels, each channel serving as a unit including one or more of the half bridges, and

the first external terminal is provided for each of the channels.

Further, in the fifth configuration described above the semiconductor device may have a configuration (sixth configuration) in which the channel includes a pair of the half bridges.

Further, in the sixth configuration described above, the semiconductor device may have a configuration (seventh configuration) in which

the pair of half bridges include a first half bridge (52) and a second half bridge (53),

the semiconductor device includes a first output terminal (OUTx) connected to a first node (N1) to which the upper side transistor and the lower side transistor that are included in the first half bridge are connected and a second output terminal (OUTy) connected to a second node (N2) to which the upper side transistor and the lower side transistor that are included in the second half bridge are connected, and

the first external terminal is arranged by being sandwiched by the first output terminal and the second output terminal in plan view of the semiconductor device.

Further, in any one of the second through seventh configurations described above, the semiconductor device may have a configuration (eighth configuration) including:

a first amplifier input terminal (AINxP) to which the first input terminal of the first amplifier and the first end of the second internal wire are connected;

a second amplifier input terminal (AINxN) connected to a second input terminal of the first amplifier; and

a grounding switch (SWGx) connected to and between the second input terminal of the first amplifier and a ground end.

Further, in any one of the first through eighth configurations described above, the semiconductor device may have a configuration (ninth configuration) including:

at least one group including

a plurality of second external terminals (PGND5 through PGND7, PGND1 through PGND4) that include at least any one of the first external terminals (PGND1 through PGND7) or that do not include the first external terminals,

a second amplifier (62, 63) or a second comparator (CMP2, CMP3),

a plurality of third internal wires each having a first end connected to a respective one of the plurality of second external terminals,

a fourth internal wire having a first end connected to a first input terminal of the second amplifier or the second comparator, and

a second switch (SW2, SW3) configured to select one second end to be connected to a second end of the fourth internal wire from among the second ends of the plurality of third internal wires.

Further, another aspect of the present disclosure relates to a current detection system that has a configuration (tenth configuration) including:

the semiconductor device according to the ninth configuration described above;

a first shunt resistor connected to one of the plurality of first external terminals; and

a second shunt resistor connected to one of the plurality of second external terminals for each group.

Further, still another aspect of the present disclosure relates to a current detection system that has a configuration (eleventh configuration) including:

the semiconductor device according to the ninth configuration described above; and

a plurality of shunt resistors, in which

each group of external terminals included in the plurality of first external terminals and the plurality of second external terminals is short-circuited, and

each of the shunt resistors is connected for each short-circuited node.

Further, yet another aspect of the present disclosure relates to a current detection system that has a configuration (twelfth configuration) including:

the semiconductor device according to any one of the second through eighth configurations described above; and

a shunt resistor connected to a node in which all of the first external terminals are short-circuited.

Further, yet another aspect of the present disclosure relates to a motor drive system (10X) that has a configuration (thirteenth configuration) including:

the semiconductor device according to any one of the fifth through seventh configurations described above including a driver (5) that has a pair of the half bridges and is configured to drive an electric motor (M); and

the shunt resistor.

Further, yet another aspect of the present disclosure relates to a vehicle (X) that has a configuration (fourteenth configuration) including:

the motor drive system according to the thirteenth configuration.

The present disclosure can, for example, be used in an on-vehicle motor drive system, etc.

The present disclosure contains subject matter related to that disclosed in Japanese Priority Patent Application JP 2025-005649 filed in the Japan Patent Office on January 15, 2025, the entire content of which is hereby incorporated by reference.

What is claimed is:

1. A semiconductor device comprising:
a plurality of first external terminals configured such that a voltage signal as a detection target is applicable thereto;
a first amplifier or a first comparator;
a plurality of first internal wires each having a first end connected to a respective one of the plurality of first external terminals;
a second internal wire having a first end connected to a first input terminal of the first amplifier or the first comparator; and
a first switch configured to select one second end to be connected to a second end of the second internal wire from among the second ends of the plurality of first internal wires.

2. The semiconductor device according to claim 1, wherein each of the first external terminals is configured to allow a shunt resistor for current/voltage conversion to be externally connected thereto.

3. The semiconductor device according to claim 2, wherein each of the first external terminals is a ground terminal connectable to a ground end via the shunt resistor.

4. The semiconductor device according to claim 2, wherein each of the first external terminals is a power supply terminal connectable to an application terminal of a power supply voltage via the shunt resistor.

5. The semiconductor device according to claim 3, wherein
a half bridge is configured such that an upper side transistor and a lower side transistor are connected in series,
the semiconductor device includes a plurality of channels, each channel serving as a unit including one or more of the half bridges, and
the first external terminal is provided for each of the channels.

6. The semiconductor device according to claim 5, wherein the channel includes a pair of the half bridges.

7. The semiconductor device according to claim 6, wherein
the pair of half bridges include a first half bridge and a second half bridge,
the semiconductor device includes a first output terminal connected to a first node to which the upper side transistor and the lower side transistor that are included in the first half bridge are connected and a second output terminal connected to a second node to which the upper side transistor and the lower side transistor that are included in the second half bridge are connected, and
the first external terminal is arranged by being sandwiched by the first output terminal and the second output terminal in plan view of the semiconductor device.

8. The semiconductor device according to claim 2, further comprising:
a first amplifier input terminal to which the first input terminal of the first amplifier and the first end of the second internal wire are connected;
a second amplifier input terminal connected to a second input terminal of the first amplifier; and
a grounding switch connected to and between the second input terminal of the first amplifier and a ground end.

9. The semiconductor device according to claim 1, further comprising:
at least one group including
a plurality of second external terminals that include at least any one of the first external terminals or that do not include the first external terminals,
a second amplifier or a second comparator,
a plurality of third internal wires each having a first end connected to a respective one of the plurality of second external terminals,
a fourth internal wire having a first end connected to a first input terminal of the second amplifier or the second comparator, and
a second switch configured to select one second end to be connected to a second end of the fourth internal wire from among the second ends of the plurality of third internal wires.

10. A current detection system comprising:
the semiconductor device according to claim 9;
a first shunt resistor connected to one of the plurality of first external terminals; and
a second shunt resistor connected to one of the plurality of second external terminals for each group.

11. A current detection system comprising:
the semiconductor device according to claim 9; and
a plurality of shunt resistors, wherein
each group of external terminals included in the plurality of first external terminals and the plurality of second external terminals is short-circuited, and
each of the shunt resistors is connected for each short-circuited node.

12. A current detection system comprising:
the semiconductor device according to claim 2; and
a shunt resistor connected to a node in which all of the first external terminals are short-circuited.

13. A motor drive system comprising:
the semiconductor device according to claim 5 including a driver that has a pair of the half bridges and is configured to drive an electric motor; and
the shunt resistor.

14. A vehicle comprising:
the motor drive system according to claim 13.
